(19) United States
(12) Patent Application Publication
(10) Pub. No.: US 2025/0343059 A1
(43) Pub. Date: Nov. 6, 2025

(54) SUBSTRATE PROCESSING SYSTEM

(71) Applicant: SAMSUNG ELECTRONICS CO., LTD., Suwon-si (KR)

(72) Inventors: Jinoh IM, Suwon-si (KR); DONGHOON KWON, Suwon-si (KR)

(73) Assignee: SAMSUNG ELECTRONICS CO., LTD., Suwon-si (KR)

(21) Appl. No.: 18/984,079

(22) Filed: Dec. 17, 2024

(30) Foreign Application Priority Data
May 3, 2024 (KR) 10-2024-0059107

(51) Int. Cl. H01L 21/67; H01L 21/677

(52) U.S. Cl. CPC H01L 21/67103; H01L 21/67248; H01L 21/67748; H01L 21/67167

(57) ABSTRACT

A substrate processing system may include a substrate moving device that includes a transfer chamber including a central space, a transfer arm in the central space and configured to move a substrate, and a first heater configured to contact the transfer arm and heat the substrate. The transfer arm may include an arm body configured to rotate about a first axis, and a substrate support configured to support the substrate and connected to the arm body. The first heater may overlap with at least a portion of an outer surface of the substrate support.

### CROSS-REFERENCE TO RELATED APPLICATION

This U.S. non-provisional patent application claims priority under 35 U.S.C. § 119 to Korean Patent Application No. 10-2024-0059107, filed on May 3, 2024, in the Korean Intellectual Property Office, the entire contents of which are hereby incorporated by reference.

### BACKGROUND

### 1. Field

Embodiments of the present disclosure relate to a substrate processing system and, more specifically, relates to a substrate processing system capable of maintaining and controlling a temperature of a substrate by heating the substrate while a transfer arm moves the substrate to a process chamber.

### 2. Brief Description of Background Art

A semiconductor device may be manufactured through several processes. Semiconductor processing may be performed in a process chamber. The process chamber may perform processes such as etching, deposition, cleaning, and heating on the substrate. For efficiency of semiconductor processing, the substrate processing system may include a plurality of process chambers and a central chamber connecting the plurality of process chambers, and the central chamber may include a transfer arm capable of moving the substrate to the multiple process chambers.

### SUMMARY

According to embodiments of the present disclosure, a substrate processing system that does not require a separate heating chamber may be provided.

According to embodiments of the present disclosure, a substrate processing system that is capable of maintaining and controlling a temperature of a substrate when moving the substrate from a central chamber to a process chamber may be provided.

According to embodiments of the present disclosure, a substrate processing system that is capable of heating a lower surface of a substrate and simultaneously measuring a temperature of an upper surface of the substrate may be provided.

According to embodiments of the present disclosure, a substrate processing system that is capable of reducing heat loss of a substrate may be provided.

According to embodiments of the present disclosure, a substrate processing system may be provided and include a substrate moving device including: a transfer chamber including a central space; a transfer arm in the central space and configured to move a substrate; and a first heater configured to contact the transfer arm and heat the substrate, wherein the transfer arm includes: an arm body configured to rotate about a first axis; and a substrate support configured to support the substrate and connected to the arm body, and wherein the first heater overlaps with at least a portion of an outer surface of the substrate support.

According to embodiments of the present disclosure, a substrate processing system may be provided and include: a substrate processing device; and a substrate moving device connected to the substrate processing device and configured to supply a substrate to the substrate processing device, wherein the substrate moving device includes: a transfer chamber including a central space; and a transfer arm in the central space and configured to move the substrate to the substrate processing device, wherein the transfer arm includes: an arm body configured to rotate about a first axis; and a substrate support configured to support the substrate and connected to the arm body, wherein the substrate processing device includes: a process chamber configured to perform a process on the substrate; and a connector that connects the process chamber to the transfer chamber, wherein the transfer arm is configured to pass through the connector, and wherein the connector includes at least one heater configured to emit heat.

According to embodiments of the present disclosure, a substrate processing system may be provided and include: a substrate moving device including: a transfer chamber including a central space; a transfer arm in the central space and configured to move a substrate; and a first heater configured to contact the transfer arm and heat the substrate, wherein the transfer arm includes: an arm body configured to rotate about a first axis; and a substrate support connected to the arm body and configured to support the substrate, wherein the first heater is connected to the substrate support, and wherein a level of the first heater is lower than or equal to a level of the substrate support.

Problems solved by and advantages of embodiments of the present disclosure are not limited to the problems and advantages mentioned above, and other problems that are solved and other advantageous not mentioned will be clearly understood by those skilled in the art from the description below.

Specific details of other embodiments are included in the detailed description and drawings.

### BRIEF DESCRIPTION OF DRAWINGS

Example embodiments will be more clearly understood from the following brief description taken in conjunction with the accompanying drawings. The accompanying drawings represent non-limiting example embodiments as described herein.

FIG. 1 is a perspective view illustrating a substrate processing system according to embodiments of the present disclosure.

FIG. 2 is a plan view illustrating a substrate processing system according to embodiments of the present disclosure.

FIG. 3 is a perspective view illustrating a transfer arm according to embodiments of the present disclosure.

FIG. 4 is a front view illustrating a transfer arm according to embodiments of the present disclosure.

FIG. 5 is a plan view illustrating a transfer arm according to embodiments of the present disclosure.

FIG. 6 is a perspective view illustrating a transfer arm and a substrate processing device according to embodiments of the present disclosure.

FIG. 7 is a front view illustrating a load lock chamber and a transfer arm according to embodiments of the present disclosure.

FIG. 8 is a front view illustrating a load lock chamber and a transfer arm according to embodiments of the present disclosure.

FIG. 9 is a front view illustrating a load lock chamber, a transfer arm, and a substrate processing device according to embodiments of the present disclosure.

FIG. 10 is a front view illustrating a load lock chamber, a transfer arm, and a substrate processing device according to embodiments of the present disclosure.

FIG. 11 is a front view illustrating a transfer arm and a first heater according to embodiments of the present disclosure.

FIG. 12 is a front view illustrating a transfer arm and a first heater according to embodiments of the present disclosure.

FIG. 13 is a front view illustrating a transfer arm and a first heater according to embodiments of the present disclosure.

FIG. 14 is a front view illustrating a transfer arm and a first heater according to embodiments of the present disclosure.

FIG. 15 is a front view illustrating a transfer arm and a first heater according to embodiments of the present disclosure.

FIG. 16 is a front view illustrating a transfer arm, a second heater, and a sensor according to embodiments of the present disclosure.

FIG. 17 is a front view illustrating the transfer arm, a second heater, and a sensor according to embodiments of the present disclosure.

FIG. 18 is a front view illustrating a transfer arm and a substrate processing device according to embodiments of the present disclosure.

### DETAILED DESCRIPTION

Hereinafter, non-limiting example embodiments of the present disclosure will be described with reference to the attached drawings. The same reference numerals may refer to the same elements throughout the specification.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, described directions may include a first direction D1, a second direction D2 crossing the first direction D1, and a third direction D3 crossing each of the first direction D1 and the second direction D2.

Advantages and features of embodiments (including methods) the present disclosure will become clear by referring to the example embodiments described in detail below along with the accompanying drawings. However, embodiments of the present disclosure are not limited to the example embodiments disclosed below and may be implemented in various different forms or methods. The example embodiments that are described are only provided to ensure that the disclosure of the present disclosure is complete, and to fully inform those skilled in the art of the present disclosure of the scope of the present disclosure.

The terms used in this specification are for describing example embodiments and are not intended to limit embodiments of the present disclosure. As used herein, singular forms also include plural forms, unless specifically stated otherwise in the context. As used in the specification, “comprises” (or “includes”) and/or “comprising” (or “including”) specify the presence of the stated features, steps, operations, elements, and/or components, but do not preclude the presence or addition of one or more other features, steps, operations, elements, components, and/or groups thereof. Hereinafter, non-limiting example embodiments of the present disclosure will be described in detail.

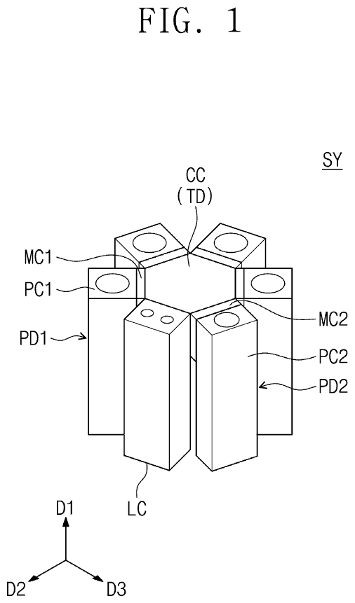

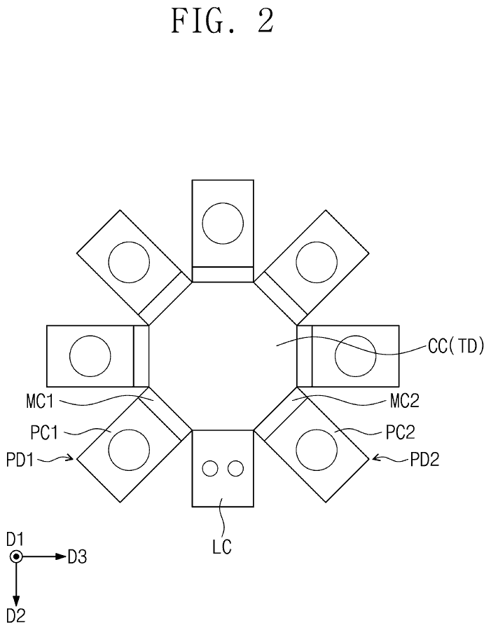

FIG. 1 is a perspective view illustrating a substrate processing system SY according to embodiments of the present disclosure, and FIG. 2 is a plan view illustrating a substrate processing system SY according to embodiments of the present disclosure.

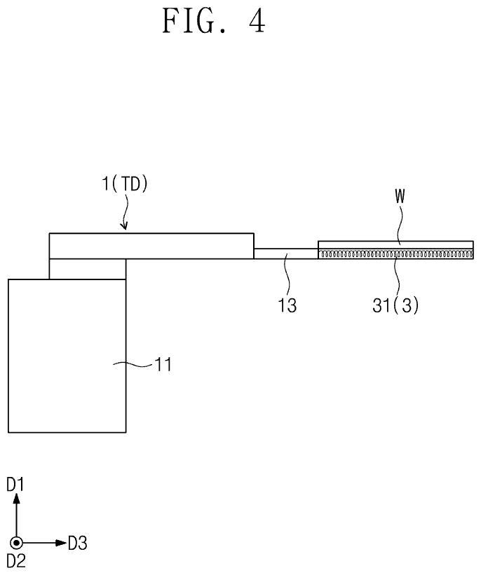

Referring to FIGS. 1 and 2, a substrate processing system SY may be provided. The substrate processing system SY may include a substrate processing device (e.g., a first substrate processing device PD1 or a second substrate processing device PD2), a substrate moving device TD, and a load lock chamber LC. The substrate processing device (e.g., the first substrate processing device PD1 or the second substrate processing device PD2) may include a process chamber (e.g., a first process chamber PC1 or a second process chamber PC2) and a connection module (e.g., a first connection module MC1 or a second connection module MC2) (also referred to as a “connector”). The process chamber (e.g., the first process chamber PC1 or the second process chamber PC2) may receive a substrate W (see FIG. 4) from the outside through the connection module (e.g., the first connection module MC1 or the second connection module MC2). In this specification, the substrate W may be a silicon (Si) wafer. However, embodiments of the present disclosure are limited thereto. The process chamber (e.g., the first process chamber PC1 or the second process chamber PC2) may perform a process related to semiconductor manufacturing on the substrate W. The semiconductor manufacturing process may include an oxidation process, a photo process, an etching process, a thin layer process, a metal wiring process, a substrate heating process, a substrate cleaning process, and a packaging process. However, embodiments of the present disclosure are not limited thereto. The process chamber (e.g., the first process chamber PC1 or the second process chamber PC2) may provide a process space. The process space may be a vacuum. However, embodiments of the present disclosure are not limited thereto, and the process space may maintain a high vacuum environment. The connection module (e.g., the first connection module MC1 or the second connection module MC2) may connect the process chamber (e.g., the first process chamber PC1 or the second process chamber PC2) and the outside of the substrate processing device (e.g., the first substrate processing device PD1 or the second substrate processing device PD2). The connection module (e.g., the first connection module MC1 or the second connection module MC2) may provide a connection space. The connection space may be connected to the outside of the substrate processing device (e.g., the first substrate processing device PD1 or the second substrate processing device PD2) or may be sealed. The connection space may have a lower vacuum than the process space. The connection space may allow the process space to efficiently maintain a high vacuum environment. The connection module (e.g., the first connection module MC1 or the second connection module MC2) will be described later. The substrate processing system SY may include a plurality of substrate processing devices. For example, the substrate processing system SY may include a first substrate processing device PD1 and a second substrate processing device PD2. The first substrate processing device PD1 may include a first connection module MC1 and a first process chamber PC1. The second substrate processing device PD2 may include a second connection module MC2 and a second process chamber PC2.

The load lock chamber LC may store the substrate W. The load lock chamber LC may store a plurality of substrates W. The load lock chamber LC may receive a substrate W from the outside. The load lock chamber LC may receive the substrate W from an atmospheric pressure environment. The load lock chamber LC may be connected to a vacuum pump. An interior of the load lock chamber LC may be exposed to atmospheric pressure when the load lock chamber LC receives the substrate W from the outside. After the load lock chamber LC receives the substrate W, a vacuum pump may create a vacuum environment inside the load lock chamber LC.

The substrate moving device TD may include a transfer chamber CC. The transfer chamber CC may provide a central space. The transfer chamber CC may be connected to the load lock chamber LC and the substrate processing devices (e.g., the first substrate processing device PD1 and the second substrate processing device PD2). The substrate processing devices (e.g., the first substrate processing device PD1 and the second substrate processing device PD2) may be connected to respective sides of the transfer chamber CC. The load lock chamber LC may be connected to another side of the transfer chamber CC. The substrate W taken out of the load lock chamber LC may pass through the transfer chamber CC and move to a substrate processing device (e.g., the first substrate processing device PD1 or the second substrate processing device PD2). The substrate W taken out of the first substrate processing device PD1 may pass through the transfer chamber CC and move to the second substrate processing device PD2. The substrate moving device TD may further include a transfer arm 1, a heater 3, a sensor 5, and a heater driver 7, which will be described later.

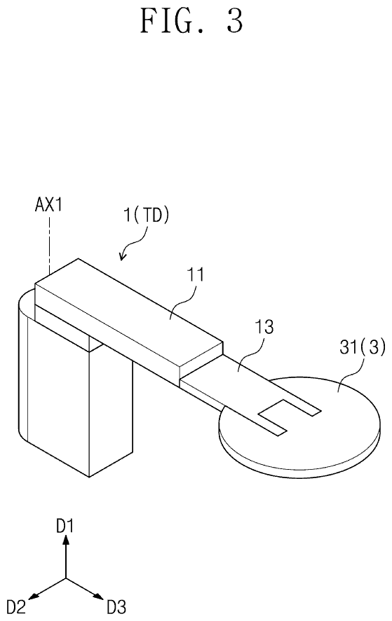

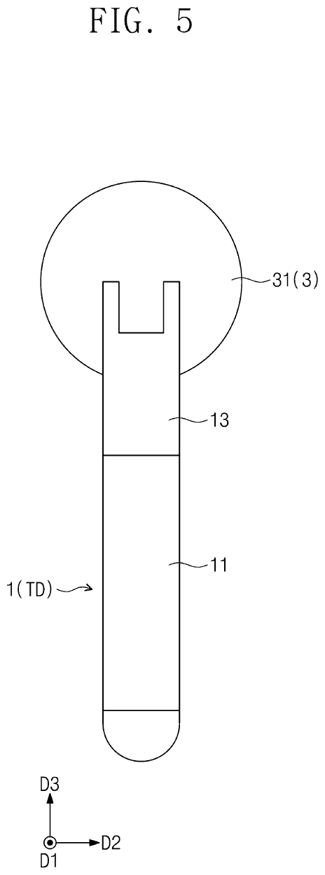

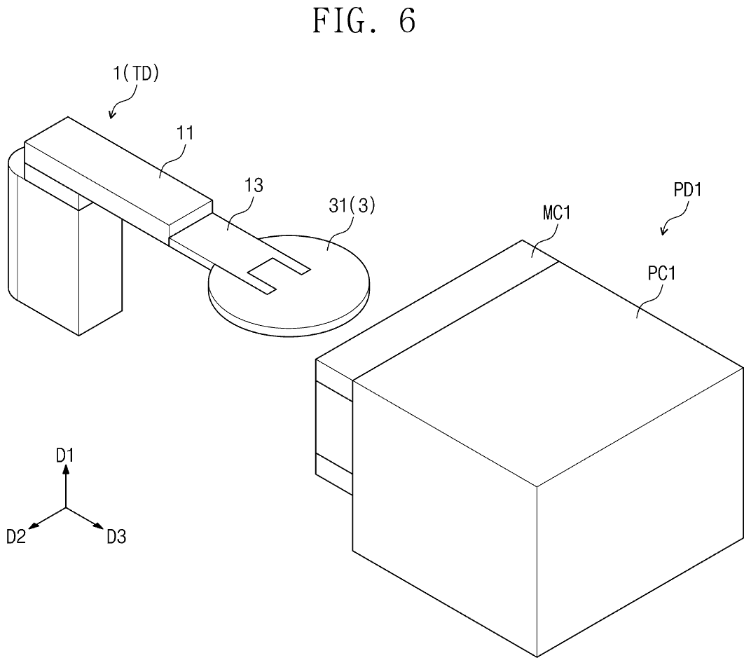

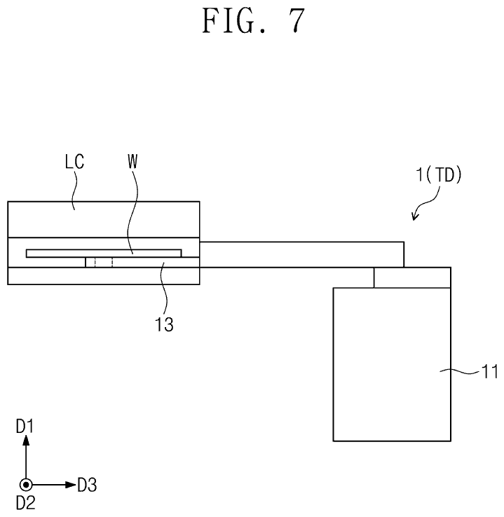

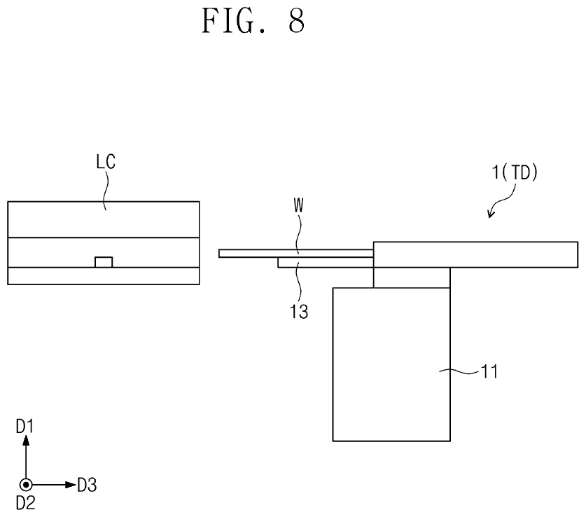

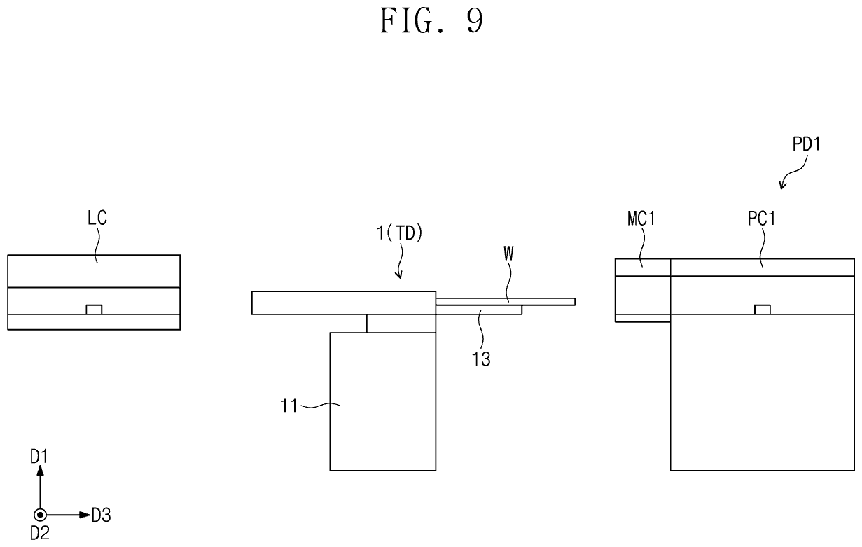

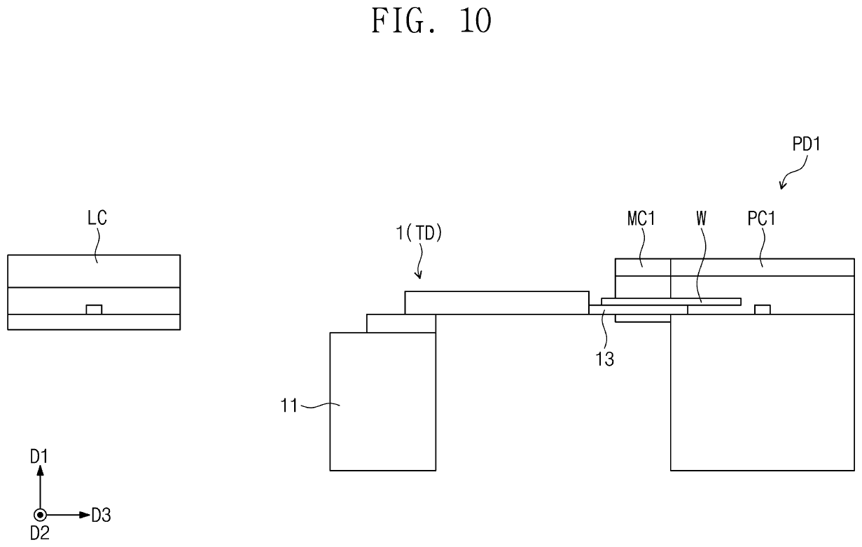

FIG. 3 is a perspective view illustrating a transfer arm 1 according to embodiments of the present disclosure, FIG. 4 is a front view illustrating a transfer arm 1 according to embodiments of the present disclosure, FIG. 5 is a plan view illustrating a transfer arm 1 according to embodiments of the present disclosure, FIG. 6 is a perspective view illustrating a transfer arm 1 and a first substrate processing device PD1 according to embodiments of the present disclosure, FIG. 7 is a front view illustrating a load lock chamber LC and a transfer arm 1 according to embodiments of the present disclosure, FIG. 8 is a front view illustrating a load lock chamber LC and a transfer arm 1 according to embodiments of the present disclosure, FIG. 9 is a front view illustrating a load lock chamber LC, a transfer arm 1, and a first substrate processing device PD1 according to embodiments of the present disclosure, and FIG. 10 is a front view illustrating a load lock chamber LC, a transfer arm 1, and a first substrate processing device PD1 according to embodiments of the present disclosure.

The transfer arm 1 may be located in the central space. The transfer arm 1 may move the substrate W. The transfer arm 1 may support the substrate W. The transfer arm 1 may include an arm body 11 and a substrate support 13. The arm body 11 may rotate about a first axis AX1 extending in the first direction D1. The arm body 11 may be variously changed in a height in a vertical direction. The arm body 11 may move in a horizontal direction. The arm body 11 may extend in a second direction D2 and a third direction D3 perpendicular to the first direction D1. The substrate support 13 may be connected to the arm body 11. The substrate support 13 may support the substrate W. Referring to FIG. 7, the transfer arm 1 may receive a substrate W from the load lock chamber LC. The transfer arm 1 may insert the substrate support 13 into the load lock chamber LC. The substrate support 13 may move by the arm body 11 to support the substrate. Referring to FIGS. 8 and 9, the transfer arm 1 may rotate while supporting the substrate W. The transfer arm 1 may rotate and move the substrate W toward one of the plurality of substrate processing devices (e.g., the first substrate processing device PD1 or the second substrate processing device PD2). For example, the transfer arm 1 may move the substrate W to a first substrate processing device PD1. Hereinafter, in this specification, the transfer arm 1 will be described assuming that the transfer arm 1 moves the substrate W to the first substrate processing device PD1. However, the same description may be applied when the transfer arm 1 moves the substrate W to another substrate processing device (e.g., the second substrate processing device PD2). Referring to FIG. 10, the transfer arm 1 may input the substrate W into the first process chamber PC1 through a first connection module MC1. The transfer arm 1 may pass through a first connection module MC1.

The heater 3 may include a first heater 31. The first heater 31 may heat the substrate W. The first heater 31 may heat a lower surface of the substrate W. The first heater 31 may include a heat source (e.g., a heating wire, a heat ray source, or a laser light source) to heat the substrate W. The first heater 31 may heat the substrate W by being in direct contact with the substrate W. The first heater 31 may heat the substrate W using radiant heat without being in contact with the substrate W. However, a configuration of the first heater 31 is not limited thereto. The first heater 31 may further include other components capable of heating the substrate W. The first heater 31 may maintain the lower surface of the substrate W at about 300° C. or less. The first heater 31 may heat the substrate support 13. However, a function of the first heater 31 is not limited thereto. The first heater 31 may be combined with (e.g., contact) the transfer arm 1. More specifically, the first heater 31 may be combined with (e.g., contact) the substrate support 13. A level of an upper surface of the first heater 31 may be the same as a level of an upper surface of the substrate support 13. However, a level of the first heater 31 is not limited thereto. The level of the first heater 31 may be lower than or equal to the level of the substrate support 13. A level of the first heater 31 may be lower than a level of the substrate W. The first heater 31 may be provided with a recessed portion so that the first heater 31 may be combined with (e.g., contact) the substrate support 13. The substrate support 13 may be combined with (e.g., contact) the first heater 31 by being located in the recessed portion. However, embodiments of the present disclosure are not limited thereto. The first heater 31 may be in contact with the substrate support 13. The first heater 31 may be spaced downward from the substrate support 13. This will be described later. The first heater 31 may surround at least a portion of an outer surface of the substrate support 13. More specifically, as illustrated in FIG. 5, the first heater 31 may surround (e.g., overlap with) at least a portion of the outer surface of the substrate support 13 when viewed in a plan view. The first heater 31 may have a circular plate shape. However, a shape of the first heater 31 is not limited thereto. The first heater 31 may have various shapes capable of heating at least a portion of the substrate W. The first heater 31 may have a rectangular shape capable of heating an entirety of the substrate W.

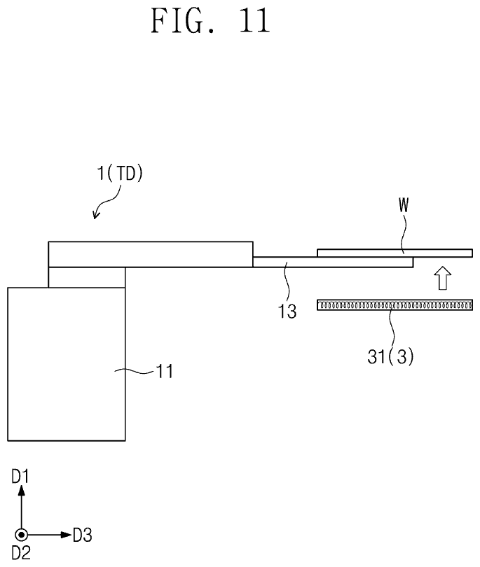

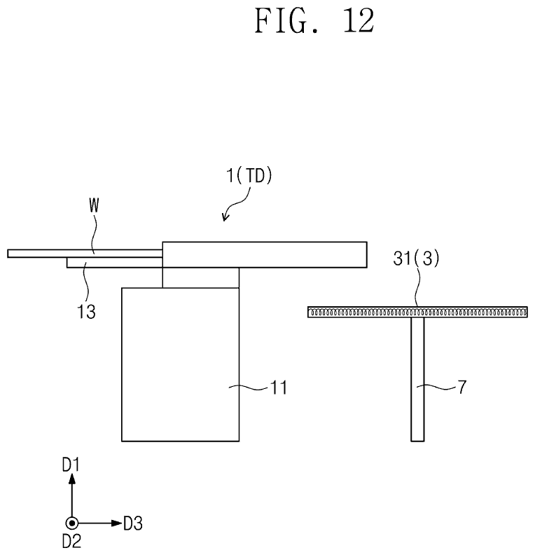

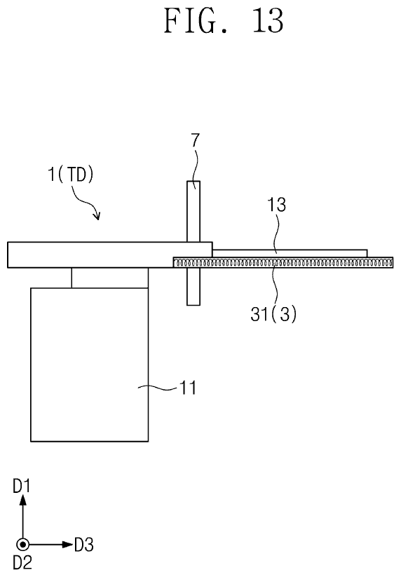

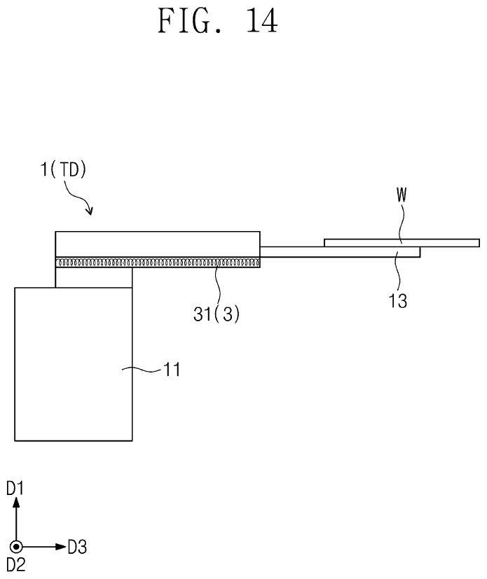

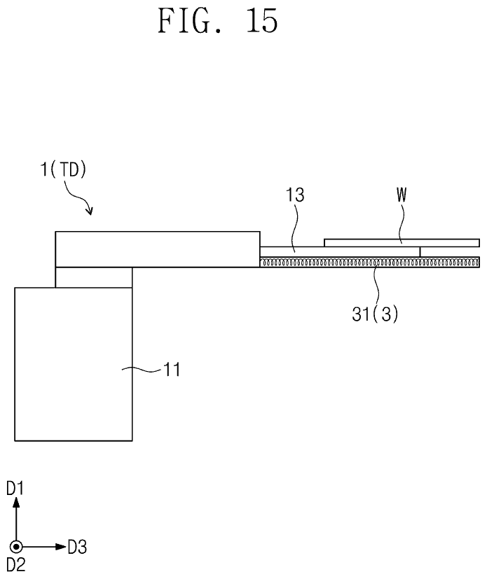

FIG. 11 is a front view illustrating a transfer arm 1 and a first heater 31 according to embodiments of the present disclosure, FIG. 12 is a front view illustrating a transfer arm 1 and a first heater 31 according to embodiments of the present disclosure, FIG. 13 is a front view illustrating a transfer arm 1 and a first heater 31 according to embodiments of the present disclosure, FIG. 14 is a front view illustrating a transfer arm 1 and a first heater 31 according to embodiments of the present disclosure, and FIG. 15 is a front view illustrating a transfer arm 1 and a first heater 31 according to embodiments of the present disclosure.

FIGS. 11, 12, 13, 14, and 15 show various positions that the first heater 31 may have in the transfer arm 1. Referring to FIG. 11, the first heater 31 may be located externally and then combined with (e.g., contact) the transfer arm 1. The first heater 31 may stand in the central space and then be combined with (e.g., contact) the transfer arm 1. Referring to FIG. 12, the first heater 31 may be arranged to be spaced apart from the transfer arm 1 in the central space. The first heater 31 may be moved by a heater driver 7. The heater driver 7 may include at least one actuator. The heater driver 7 may be located in the central space. The heater driver 7 may be spaced apart from the transfer arm 1. The heater driver 7 may move the first heater 31 up, down, left, and right. When the transfer arm 1 rotates onto the first heater 31 while supporting the substrate W, the heater driver 7 may move the first heater 31 to combine (e.g., contact) the first heater 31 with the transfer arm 1. However, a role of the heater driver 7 is not limited thereto. The heater driver 7 may move the first heater 31 under the substrate support 13. After the heater driver 7 moves the first heater 31 under the substrate support 13, the heater driver 7 may lift the first heater 31 so that the first heater 31 and the transfer arm 1 are combined (e.g., contacted). Referring to FIG. 13, the heater driver 7 may be combined with (e.g., contact) the transfer arm 1. The heater driver 7 may be combined with the arm body 11. As the heater driver 7 is combined with the transfer arm 1, the first heater 31 may move and rotate together with the transfer arm 1. The first heater 31 may heat the substrate W by combining with (e.g., contacting) the substrate support 13 when the transfer arm 1 moves the substrate W. The first heater 31 may heat the substrate W by being positioned under the substrate support 13 when the transfer arm 1 moves the substrate W. A level of the first heater 31 may be the same as a level of the substrate support 13 or may be lower than the level of the substrate support 13.

Referring to FIGS. 14 and 15, the first heater 31 may be located inside the arm body 11. The first heater 31 may be located inside the arm body 11 and then protrude out of the arm body 11. For example, at least one actuator may be provided and may be configured to move the first heater 31 in and/or out of the arm body 11. The first heater 31 may be located inside the arm body 11 and protrude out of the arm body 11 when the substrate W needs to be heated. A level of the first heater 31 may be lower than a level of the substrate support 13. More specifically, a level of an upper surface of the first heater 31 may be lower than a level of a lower surface of the substrate support 13.

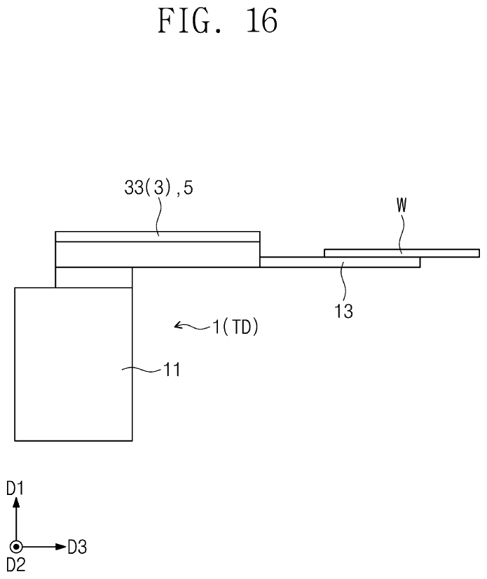

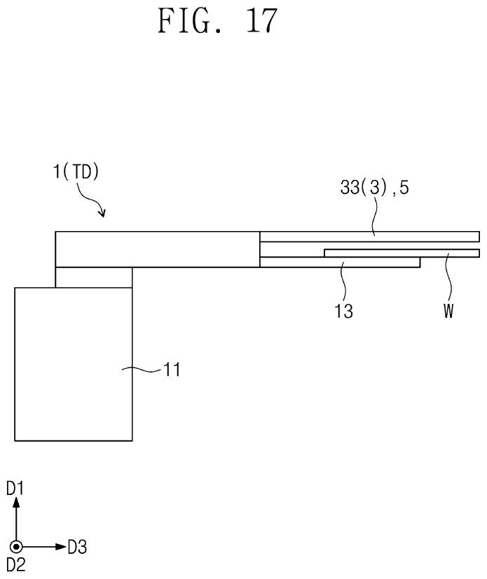

FIG. 16 is a front view illustrating a transfer arm 1, a second heater 33, and a sensor 5 according to embodiments of the present disclosure, and FIG. 17 is a front view illustrating the transfer arm 1, a second heater 33, and a sensor 5 according to embodiments of the present disclosure.

The heater 3 may further include a second heater 33. The second heater 33 may heat an upper surface of the substrate W. The second heater 33 may include a heat source (e.g., a heating wire, a heat ray source, or a laser light source) to heat the substrate W. However, a configuration of the second heater 33 is not limited thereto. The second heater 33 may further include other components capable of heating the substrate W. A level of the second heater 33 may be higher than a level of the substrate W. A level of a lower surface of the second heater 33 may be higher than a level of an upper surface of the substrate support 13. A level of a lower surface of the second heater 33 may be higher than a level of an upper surface of the first heater 31. Referring to FIG. 16, the second heater 33 may be located inside the arm body 11 and then protrude out of the arm body 11. For example, at least one actuator may be provided and may be configured to move the second heater 33 in and/or out of the arm body 11.

The substrate moving device TD may further include a sensor 5 instead of the second heater 33. The sensor 5 may be combined with (e.g., contact) the transfer arm 1. The sensor 5 may be located inside the transfer arm 1 and then protrude to the outside of the transfer arm 1. For example, at least one actuator may be provided and may be configured to move the sensor 5 in and/or out of the transfer arm 1. The sensor 5 may measure a temperature of the substrate W. The sensor 5 may measure a temperature of an upper surface of the substrate W.

The sensor 5 may be spaced upward from the first heater 31. A level of the sensor 5 may be higher than a level of the first heater 31. However, the substrate moving device TD does not have to include only one from among the second heater 33 and the sensor 5. The substrate moving device TD may include both the second heater 33 and the sensor 5. The second heater 33 and the sensor 5 may be located at the same position. The upper surface of the substrate W may be heated by the second heater 33 and the temperature may be measured by the sensor 5.

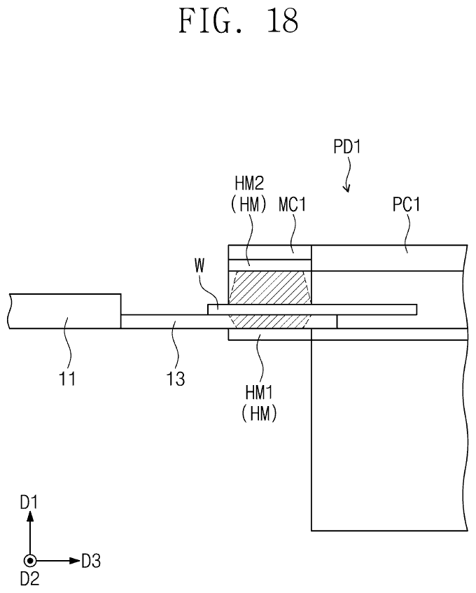

FIG. 18 is a front view illustrating a transfer arm 1 and a substrate processing device PD1 according to embodiments of the present disclosure.

The first connection module MC1 may include a heating module HM (e.g., a heater) capable of dissipating heat. The heating module HM may include a heat source (e.g., a heat ray source or a laser light source) capable of emitting a laser. The heating module HM may include a first heating module HM1 (e.g., a first heater) and a second heating module HM2 (e.g., a second heater). The first heating module HM1 may be located at a lower portion of a connection space. When the substrate W enters the connection space, a level of the first heating module HM1 may be lower than a level of the substrate support 13. When the substrate W enters the connection space, a level of the first heating module HM1 may be lower than a level of the first heater 31. The second heating module HM2 may be located at an upper portion of the connection space. The second heating module HM2 may heat the upper surface of the substrate W. When the substrate W enters the connection space, a level of the second heating module HM2 may be higher than a level of the substrate support 13. A temperature of the substrate W may be maintained and controlled by the heating module HM. According to embodiments of the present disclosure, the substrate processing system SY may be configured to maintain and control the temperature of the substrate W when the substrate W is moved. The heater 3 may maintain and control the temperature of the substrate W as the substrate W moves from the load lock chamber LC to the process chamber (e.g., the first process chamber PC1 or the second process chamber PC2). The heater 3 may maintain and control the temperature of the substrate W as the substrate W moves from the first process chamber PC1 to the second process chamber PC2. The heater 3 may maintain the temperature of the substrate W below 300° C. when the substrate W is moved to different process chambers (e.g., the first process chamber PC1 and the second process chamber PC2) and when the substrate w is moved from the load lock chamber LC to the process chamber (e.g., the first process chamber PC1 or the second process chamber PC2).

According to embodiments of the present disclosure, the substrate processing system SY may be configured to maintain and control the temperature of the substrate W without a separate process chamber to increase the temperature of the substrate W by a heater (e.g., the heater 3). The temperature required to maintain the temperature of the substrate W may be lower than when a process is performed on the substrate W. There may be no need for a separate process chamber to increase the temperature of the substrate W to control the temperature of the substrate W when the substrate W moves. As there is no need for a separate process chamber to increase the temperature of the substrate W, space utilization and process efficiency may be improved.

According to embodiments of the present disclosure, there is no need to provide a separate heating chamber.

According to embodiments of the present disclosure, the temperature of the substrate W may be maintained and controlled when moving the substrate W from a central chamber (e.g., the transfer chamber CC) to the process chambers (e.g., the first process chamber PC1 and the second process chamber PC2).

According to embodiments of the present disclosure, it is possible to heat the lower surface of the substrate W and simultaneously measure the temperature of the upper surface of the substrate W.

According to embodiments of the present disclosure, heat loss of the substrate W may be reduced.

The effects of embodiments of the present disclosure are not limited to the effects mentioned above, and other effects not mentioned may be clearly understood by those skilled in the art from the description above.

While non-limiting example embodiments are described above, a person skilled in the art may understand that many modifications and variations are made without departing from the spirit and scope of the present disclosure. Accordingly, the example embodiments of the present disclosure should be considered in all respects as illustrative and not restrictive.

What is claimed is:

1. A substrate processing system comprising:
a substrate moving device comprising:
a transfer chamber including a central space;
a transfer arm in the central space and configured to move a substrate; and
a first heater configured to contact the transfer arm and heat the substrate,
wherein the transfer arm comprises:
an arm body configured to rotate about a first axis; and
a substrate support configured to support the substrate and connected to the arm body, and
wherein the first heater overlaps with at least a portion of an outer surface of the substrate support.

2. The substrate processing system of claim 1, wherein a level of an upper surface of the substrate support and a level of an upper surface of the first heater are the same.

3. The substrate processing system of claim 1, wherein the first heater is configured to contact the arm body, and
wherein a level of an upper surface of the first heater is lower than a level of a lower surface of the substrate support.

4. The substrate processing system of claim 1, wherein the first heater comprises a heating wire,
wherein the first heater is configured to heat the substrate by being in direct contact with the substrate or by radiant heat without being in contact with the substrate.

5. The substrate processing system of claim 1, wherein the substrate moving device further comprises a second heater that is configured to contact the transfer arm, and
wherein a level of a lower surface of the second heater is higher than a level of an upper surface of the first heater.

6. The substrate processing system of claim 5, wherein the second heater is configured to be inside the transfer arm and protrude to an outside of the transfer arm.

7. The substrate processing system of claim 1, wherein the substrate moving device further comprises a sensor configured to contact the transfer arm,
wherein the sensor is spaced upward from the first heater, and
wherein the sensor is configured to be inside the transfer arm and protrude to an outside of the transfer arm.

8. The substrate processing system of claim 1, wherein the substrate moving device further comprises a heater driver in the central space, the heater driver configured to move the first heater up and down.

9. The substrate processing system of claim 8, wherein the heater driver is connected to the arm body, and
wherein the heater driver is configured to move the first heater such that the first heater comes into contact with the substrate support.

10. A substrate processing system comprising:
a substrate processing device; and
a substrate moving device connected to the substrate processing device and configured to supply a substrate to the substrate processing device, wherein the substrate moving device comprises:
a transfer chamber including a central space; and
a transfer arm in the central space and configured to move the substrate to the substrate processing device,
wherein the transfer arm comprises:
an arm body configured to rotate about a first axis; and
a substrate support configured to support the substrate and connected to the arm body,
wherein the substrate processing device comprises:
a process chamber configured to perform a process on the substrate; and
a connector that connects the process chamber to the transfer chamber,
wherein the transfer arm is configured to pass through the connector, and
wherein the connector comprises at least one heater configured to emit heat.

11. The substrate processing system of claim 10, wherein the at least one heater comprises a first heater, wherein the first heater comprises a laser light source or a heat ray source, and
wherein a level of the first heater is lower than a level of the substrate support.

12. The substrate processing system of claim 10, wherein the at least one heater comprises a first heater,
wherein the first heater comprises a laser light source or a heat ray source, and
wherein a level of the first heater is higher than a level of the substrate support.

13. The substrate processing system of claim 10, wherein the substrate moving device further comprises a first heater configured to contact the transfer arm and heat the substrate,
wherein the first heater is connected to the substrate support.

14. The substrate processing system of claim 13, wherein the first heater comprises a heat source configured to emit a laser.

15. The substrate processing system of claim 10, wherein the substrate moving device further comprises a sensor configured to contact the transfer arm,
wherein a level of the sensor is higher than a level of the substrate support, and
wherein the sensor is configured to measure a surface temperature of the substrate.

16. A substrate processing system comprising:
a substrate moving device comprising:
a transfer chamber including a central space;
a transfer arm in the central space and configured to move a substrate; and
a first heater configured to contact the transfer arm and heat the substrate,
wherein the transfer arm comprises:
an arm body configured to rotate about a first axis; and
a substrate support connected to the arm body and configured to support the substrate,
wherein the first heater is connected to the substrate support, and
wherein a level of the first heater is lower than or equal to a level of the substrate support.

17. The substrate processing system of claim 16, wherein the substrate moving device further comprises a heater driver configured to move the first heater, and
wherein the heater driver is spaced apart from the transfer arm.

18. The substrate processing system of claim 16, wherein the substrate moving device further comprises a heater driver configured to move the first heater, and
wherein the heater driver is configured to move together with the arm body.

19. The substrate processing system of claim 16, wherein the first heater is configured to heater the substrate support to 300° C. or lower.

20. The substrate processing system of claim 16, further comprising a substrate processing device comprising:
a process chamber configured to perform a process on the substrate; and
a connector comprising at least one heater configured to heat the substrate,
wherein the transfer arm is configured to pass through the connector.
